(19) United States
(12) Patent Application Publication
(10) Pub. No.: US 2016/0379902 A1
(43) Pub. Date: Dec. 29, 2016

(54) MEASUREMENT APPARATUS, MEASUREMENT METHOD, AND MANUFACTURING METHOD OF SEMICONDUCTOR DEVICE

(71) Applicant: Kabushiki Kaisha Toshiba, Minato-ku (JP)

(72) Inventors: Yoshinori HAGIO, Kuwana (JP); Nobuhiro KOMINE, Nagoya (JP)

(73) Assignee: Kabushiki Kaisha Toshiba, Minato-ku (JP)

(21) Appl. No.: 14/849,129

(22) Filed: Sep. 9, 2015

(30) Foreign Application Priority Data
Jun. 29, 2015 (JP) 2015-130224

(51) Int. Cl. H01L 21/66; H01J 37/06; H01J 37/244; H01J 37/29

(52) U.S. Cl. CPC H01L 22/26; H01J 37/292; H01J 37/06; H01J 37/244

(57) ABSTRACT

A measurement apparatus according to an embodiment includes an electron emission unit and a detection unit that detects a reflection electron reflected by a recessed shape pattern. In addition, the measurement apparatus includes a time measurement unit that measures a response time from when the electron beam is emitted to when the reflection electron is detected. Further, the measurement apparatus includes a bent amount calculation unit that calculates the amount of bent, i.e., a position deviation amount, between an upper surface portion and a bottom surface portion of the recessed shape pattern. The bent amount calculation unit calculates the amount of bent on the basis of a condition for determining the incidence path of the electron beam to the recessed shape pattern, and the response time.

### CROSS-REFERENCE TO RELATED APPLICATIONS

This application is based upon and claims the benefit of priority from Japanese Patent Application No. 2015-130224, filed on Jun. 29, 2015; the entire contents of which are incorporated herein by reference.

### FIELD

Embodiments of the present invention relate to a measurement apparatus, a measurement method, and a manufacturing method of a semiconductor device.

### BACKGROUND

One of manufacturing steps of a semiconductor device includes a step for performing etching processing to make a hole pattern in a substrate. In a case where the aspect ratio of the hole pattern is high in such a step, the hole pattern may be bent. When the hole pattern is bent, the upper and lower circuit layers cannot be correctly connected, and this may cause malfunction. Therefore, when a hole pattern is formed, it is desired to correctly measure the amount of bent of the hole pattern.

One of methods for measuring the amount of bent of the hole pattern includes a section observation of a hole pattern. In this method, a substrate is processed in a cleavage or a TEM (Transmission Electron Microscope), so that the section of the hole pattern is exposed, and is observed with an electron microscope.

However, this method is a destructive inspection, and the observed substrate is discarded as a damaged product, and therefore, the manufacturing cost is put under pressure. In addition, it takes a long time to perform a work to cause the cross section of the hole pattern to be exposed. Therefore, it is desired to measure the amount of bent of the hole pattern in a short time without destroying the substrate.

### BRIEF DESCRIPTION OF THE DRAWINGS

FIG. 1 is a figure schematically illustrating a configuration of a measurement apparatus according to an embodiment;

FIG. 2 is a figure for explaining the amount of bent of the hole pattern;

FIG. 3 is a figure for explaining a relationship of the amount of bent of the hole pattern and an incidence angle of an electron beam;

FIGS. 4A and 4B are figures for explaining a relationship of a tilt angle and a response time;

FIGS. 5A and 5B are figures for explaining the amount of bent of the hole pattern;

FIG. 6 is a flowchart illustrating a bent amount measurement processing procedure according to an embodiment;

FIGS. 7A to 7C are figures for explaining a change of a response time in a case where the incidence position of the electron beam is changed; and

FIG. 8 is a figure for illustrating a hardware configuration of a bent amount calculation unit.

### DETAILED DESCRIPTION

According to an embodiment, a measurement apparatus is provided. The measurement apparatus includes an electron emission unit that emits an electron beam and a detection unit that detects a reflection electron reflected by a recessed shape pattern which is a measurement target pattern. In addition, the measurement apparatus includes a time measurement unit that measures a response time which is a time from when the electron beam is emitted to when the reflection electron is detected. Further, the measurement apparatus includes a bent amount calculation unit that calculates, as an amount of bent of the recessed shape pattern, a position deviation amount between an upper surface portion and a bottom surface portion of the recessed shape pattern. The bent amount calculation unit calculates the amount of bent on the basis of a condition for determining the incidence path of the electron beam to the recessed shape pattern, and the response time.

A measurement apparatus, a measurement method, and a manufacturing method of a semiconductor device according to an embodiment will be hereinafter explained in details with reference to appended drawings. It should be noted that the present invention is not limited by this embodiment.

### Embodiment

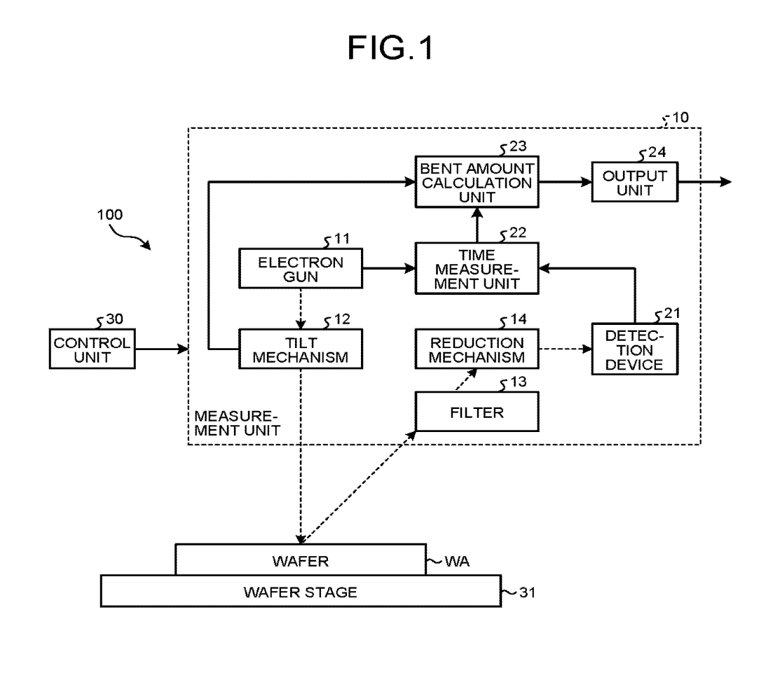

FIG. 1 is a figure schematically illustrating a configuration of a measurement apparatus according to the embodiment. The measurement apparatus 100 has a function of a scanning electron microscope (SEM), and is applied to a measurement field (metrology). The measurement apparatus 100 measures the amount of bent in a case where a high aspect ratio pattern (recessed shape pattern) is seen from the top surface.

A measurement apparatus 100 according to the present embodiment changes an incidence path condition for determining an incidence path of an electron beam to a recessed shape pattern in various manners for the recessed shape pattern such as a hole pattern and a groove pattern. For example, the measurement apparatus 100 causes the electron beam to be incident upon the recessed shape pattern with various angles. Then, the measurement apparatus 100 calculates the bending direction of the recessed shape pattern and the amount of bent on the basis of a time taken to detect a reflection electron (signal electron). In the following explanation, a case where the recessed shape pattern of the measurement target is a hole pattern will be explained, but the recessed shape pattern may be in any shape.

The measurement apparatus 100 includes a measurement unit 10, a control unit 30, and a wafer stage 31. A substrate such as a wafer WA is placed on the wafer stage 31. The control unit 30 controls the measurement unit 10. The measurement unit 10 causes the electron beam to be incident upon the hole pattern, thus calculating the bending direction of the hole pattern and the amount of bent.

The measurement unit 10 includes an electron gun 11, a tilt mechanism 12, a filter 13, a reduction mechanism 14, a detection device 21, a time measurement unit 22, a bent amount calculation unit 23, and an output unit 24.

The electron gun (electron emission unit) 11 emits the electron beam to the wafer WA on the wafer stage 31. For example, the electron gun 11 is configured to be able to emit the electron beam within a range of about 1 eV to 30000 eV. For example, the electron gun 11 according to the present embodiment emits electrons accelerated to 10000 eV.

The electron beam emitted from the electron gun 11 is delivered onto the wafer WA via the tilt mechanism 12, and is incident upon the hole pattern. The electron beam at this moment is emitted one by one with an interval of predetermined time. The electron gun 11 sends first time information, which is a time when the electron beam is emitted, to the time measurement unit 22. It should be noted that the emission time interval of each electron beam is sufficiently longer than a time it is considered to take for the signal electron generated by the electron beam reaching the surface of the wafer WA to reach the detection device 21.

The tilt mechanism 12 has a function of changing the incidence angle of the electron beam to the hole pattern by changing the tilt angle. It should be noted that the tilt angle and the incidence angle are considered to be the same. For example, the tilt mechanism 12 changes the incidence angle in the first direction (for example, X direction) by −10 degrees to +10 degrees. For example, the tilt mechanism 12 changes the incidence angle in the second direction (for example, Y direction) by −10 degrees to +10 degrees.

In this case, the incidence angle is such that, where direction perpendicular to the top surface of the wafer WA (Z direction) is adopted as a reference incidence angle, the incidence angle is an angle with respect to this incidence angle. Therefore, zero degrees of the incidence angle is the reference incidence angle. It should be noted that the incidence angle in the X direction is an angle formed by the incidence angle in the X direction (the incidence angle in the XZ plane) and the Z axis, and incidence angle in the Y direction is an angle formed by the incidence angle in the Y direction (the incidence angle in the YZ plane) and the Z axis. FIG. 1 illustrates a cross section of the wafer WA in a case where the wafer WA is cut in the XZ plane. The electron beam incident upon the wafer WA is reflected by the hole pattern and is delivered to the reduction mechanism 14. The tilt mechanism 12 sends the tilt angle to the bent amount calculation unit 23.

The filter 13 has an energy filter function. The filter 13 guides, to the detection device 21, only signal electrons having any given energy chosen from among reflection electrons and secondary electrons generated on the wafer WA as a result of emission of the electron beam to a sample such as the wafer WA from the electron gun 11. The filter 13 according to the present embodiment passes, to the detection device 21, only signal electrons of reflection electrons which are primary electrons, and shuts off the other signal electrons. More specifically, the filter 13 passes only the reflection electron of the same speed as that of the emitted electron beam.

The signal electrons having been reflected by the wafer WA and having passed through the filter 13 are delivered to the reduction mechanism 14. The reduction mechanism 14 has a function for reducing the speed of the reflection electrons from the wafer WA. The reduction mechanism 14 gives a longer delay time to a reflection electron that is incident upon the reduction mechanism 14 at a later point in time. Therefore, even in a case where the electron beam is emitted with a shorter time interval from the electron gun 11, reflection electrons can be delivered to the detection device 21 with a longer time interval. For example, the reduction mechanism 14 gives a delay time of X to the M-th (M is a natural number) reflection electron, and gives a delay time of 2X to the (M+1)-th reflection electron.

Therefore, the electron speed during detection can be reduced as compared with that of the emission. Therefore, even when electron beams are emitted successively, signal electrons corresponding to the electron beams can be separated easily, and therefore, many signal electrons can be obtained in a short time. The reduction mechanism 14 delivers the reflection electrons of which speed is reduced by the reduction mechanism 14 to the detection device 21.

The detection device (detection unit) 21 detects a signal electron. The detection device 21 includes a photomultiplier tube, and can detect a signal electron in unit of a single electron. The detection device 21 sends second time information, which indicates a time when a reflection electron is detected, to the time measurement unit 22.

The time measurement unit 22 measures a time required from when an electron beam was emitted to when it was detected (hereinafter referred to as a response time) on the basis of the first time information delivered from the electron gun 11 and the second time information delivered from the detection device 21.

The time measurement unit 22 according to the present embodiment includes a highly accurate electron time-of-flight measurement device. Therefore, the time measurement unit 22 can measure, with resolution of picoseconds or femtoseconds, a time from when the electron gun 11 emits an electron to when a reflection electron (signal electron) generated by the electron reaching the wafer WA is detected. The time measurement unit 22 sends a response time, which is a measurement result (electron time-of-flight), to the bent amount calculation unit 23.

The bent amount calculation unit 23 calculates the amount of bent of the hole pattern on the basis of the response time from the time measurement unit 22 and the tilt angle from the tilt mechanism 12. The amount of bent of the hole pattern is a position deviation amount between the upper surface portion and the bottom surface portion of the hole pattern.

The deeper position of the hole pattern an electron which is incident upon the hole pattern is reflected, the longer the response time of the electron is. Therefore, among electron beams which are incident upon the hole pattern with various tilt angles and are reflected, an electron beam that takes the longest response time is a signal electron of an electron beam reflected at the lowest bottom portion of the hole pattern.

Therefore, the bent amount calculation unit 23 calculates the amount of bent of the hole pattern on the basis of the tilt angle used with which the electron beam is incident upon the lowest bottom, the response time at this occasion, and the electron speed derived from an acceleration voltage apparatus parameter and the like. In other words, the bent amount calculation unit 23 calculates the amount of bent of the hole pattern on the basis of the tilt angle corresponding to the longest response time (hereinafter referred to as a tilt angle θₘₐₓ of the longest response time), the longest response time Tₘₐₓ, and the electron speed Ve. More specifically, the bent amount calculation unit 23 uses the following expression (1) to calculate the amount of bent of the hole pattern.

the amount of bent=Ve×Tₘₐₓ×sin(θₘₐₓ) (1)

For example, in a case where the amount of bent of the hole pattern is zero, the tilt angle of the longest response time is zero degrees. The larger the amount of bent of the hole pattern becomes, the larger, the tilt angle of the longest response time becomes. The bent amount calculation unit 23 sends the amount of bent, which is a calculation result, to the output unit 24. The output unit 24 outputs the amount of bent of the hole pattern to an external apparatus and the like.

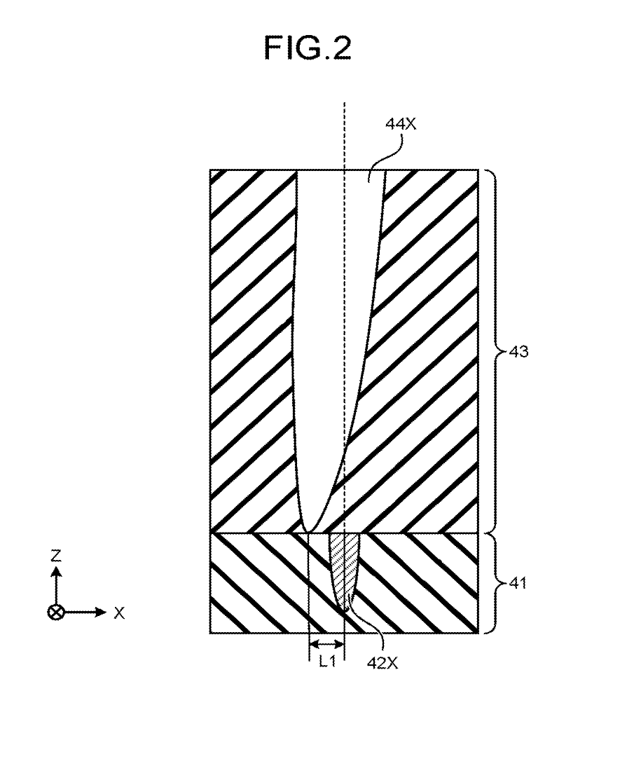

FIG. 2 is a figure for explaining the amount of bent of the hole pattern. FIG. 2 illustrates an example of a cross sectional shape of a hole pattern 44X. It should be noted that multiple hole patterns 44X are formed in the wafer WA, but in this case, the shape of a single hole pattern 44X is illustrated.

The size of the single hole pattern 44X is such that, for example, the diameter is about 100 nm, and the depth is, for example, about 5 um. In an external peripheral portion area of the wafer WA and the like, processing bent may occur in the hole pattern 44X because of a problem of a dry etching apparatus. Therefore, the hole pattern 44X may be formed in an inclined state of a predetermined angle (for example, about one degree) with respect to a direction perpendicular to the upper surface of the wafer WA. The direction of this inclination is, for example, in a center direction of the wafer WA.

A lower layer portion 41 and an upper layer portion 43 are arranged on the wafer WA. The upper layer portion 43 is arranged at the upper layer side of the lower layer portion 41. The upper layer portion 43 is an interlayer film and the like formed with a hole pattern 44X. The upper layer portion 43 is formed by performing, for example, application processing for applying a resist to an insulation film, exposure processing, development processing, etching processing using a resist pattern as a mask, and the like.

The lower layer portion 41 includes an interlayer insulation film and a wire pattern 42X formed in the interlayer insulation film. The wire pattern 42X is formed by embedding a conductive member such as metal in a hole pattern or a groove pattern. In the following explanation, a case where the wire pattern 42X in such a shape that the conductive member is embedded in the hole pattern will be explained, but the wire pattern 42X may be in any shape.

When the semiconductor device is formed, the hole pattern 44X is formed so that the wire pattern 42X and the hole pattern 44X are connected. However, the hole pattern 44X is bent, the wire pattern 42X and the hole pattern 44X cannot be correctly connected. As a result, the upper and lower circuit layers cannot be correctly connected. Therefore, in the present embodiment, the amount of bent of the hole pattern 44X is calculated, and a determination is made as to whether the upper and lower circuit layers are correctly connected or not.

When the hole pattern 44X is formed, the hole pattern 44X is formed so that the center axis of the hole pattern 44X and the center axis of the wire pattern 42X are at the same position. The position deviation amount between the center axis of the hole pattern 44X and the center axis of the wire pattern 42X corresponds to the amount of bent L1 of the hole pattern 44X.

Therefore, in the present embodiment, the position deviation amount between the center axis of the hole pattern 44X and the center axis of the wire pattern 42X is measured as the amount of bent L1 of the hole pattern 44X.

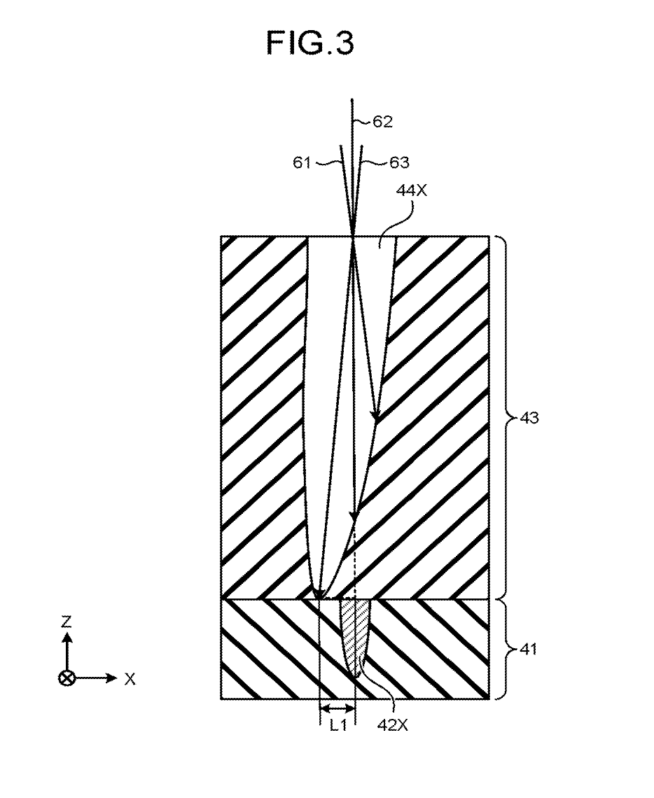

FIG. 3 is a figure for explaining a relationship of the amount of bent of the hole pattern and the incidence angle of the electron beam. When the position of the hole pattern 44X is not deviated within an XY plane, the center axis of the hole pattern 44X matches the center axis of the wire pattern 42X. When the hole pattern 44X is not bent, the center of the lowest bottom of the hole pattern 44X matches the center of the uppermost portion of the wire pattern 42X. Hereinafter explained is a case where the position of the hole pattern 44X is not deviated within the XY plane, and the hole pattern 44X is bent.

FIG. 3 illustrates incidence paths 61 to 63 of the electron beam of which incidence angle is changed. FIG. 3 illustrates a case where the tilt angle where the electron beam is incident according to the incidence path 63 is the tilt angle of the longest response time. In other words, the electron beam according to the incidence path 63 is reflected at the bottom of the lowest bottom of the hole pattern.

When the amount of bent of the hole pattern 44X is measured, the center position of the hole pattern 44X is detected in advance. The center position of the hole pattern 44X is detected on the basis of, for example, an observation image observed with an electron microscope.

Each of the incidence paths 61 to 63 is configured to pass the center of the upper surface of the hole pattern 44X. The incidence path 62 is an incidence path where the incidence angle is 0 degrees. Therefore, the incidence path 62 passes the center of the hole pattern 44X and reaches the first depth of the hole pattern 44X. The incidence path 62 is coaxial with the center axis of the wire pattern 42X.

The incidence path 63 is a path obtained by inclining the incidence angle to the negative side in X direction. The incidence path 63 passes the center of the hole pattern 44X, and reaches the lowest bottom of the hole pattern 44X (second depth). The incidence path 61 is a path obtained by inclining the incidence angle to the positive side in the X direction. The incidence path 61 passes the center of the hole pattern 44X, and reaches the third depth of the hole pattern 44X.

In this case, the following inequation holds: third depth<first depth<second depth. In other words, the following inequation holds the reaching depth of the incidence path 61<the reaching depth of the incidence path 62<the reaching depth of the incidence path 63. As described above, when the hole pattern 44X is bent, the reaching depth of the incidence path 62 where the incidence angle is 0 degrees is not the deepest. At a predetermined incidence angle (which is other than 0 degrees), the electron beam reaches the deepest portion.

When the hole pattern 44X is bent, there is a deviation in the position between the lowest bottom of the hole pattern 44X and the uppermost portion of the wire pattern 42X. The amount of bent of the hole pattern 44X is an amount according to the tilt angle of the longest response time (the tilt angle corresponding to the longest response time). In the present embodiment, the amount of bent L1 of the hole pattern 44X is calculated using the tilt angle of the longest response time.

In FIG. 3, the incidence paths 61 to 63 are changed in the X direction. Alternatively, the incidence paths 61 to 63 may be changed in the Y direction. Still alternatively, the incidence paths 61 to 63 may be changed in the X direction and the Y direction.

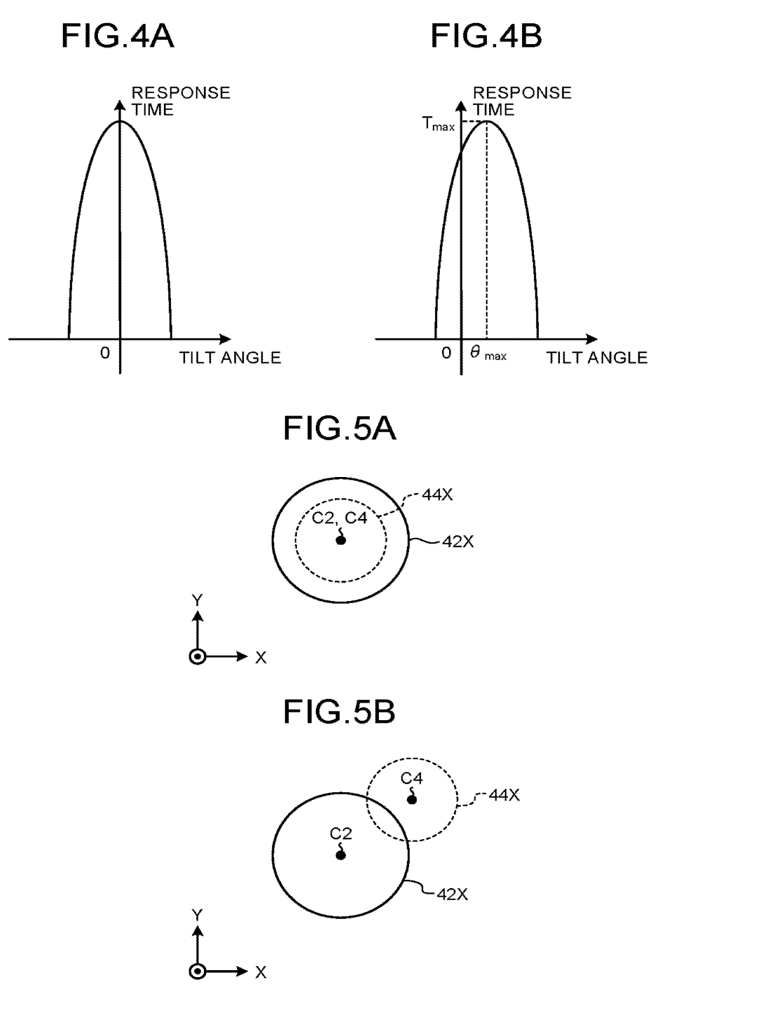

FIGS. 4A and 4B are figures for explaining a relationship between a tilt angle and a response time. FIG. 4A illustrates a relationship between a tilt angle and a response time in a case where there is no bent in the hole pattern 44X. FIG. 4B illustrates a relationship between a tilt angle and a response time in a case where there is a bent in the hole pattern 44X. In a graph illustrated in FIGS. 4A and 4B, the horizontal axis is the tilt angle, and the vertical axis is the response time.

The response time attains the maximum value in a case where a tilt angle is at a substantially center of the range of change of the tilt angle, for example, in a case where the range of change of the tilt angle is θ₁ to θ₂, the longest response time Tₘₐₓ is attained at an tilt angle of (θ₁−θ₂)/2. At a tilt angle larger than ((θ₁−θ₂)/2, the response time decreases as the tilt angle inclines in the positive direction. At a tilt angle smaller than (θ₁−θ₂)/2, the response time decreases as the tilt angle inclines in the negative direction.

In a case where there is no bent in the hole pattern 44X, the response time of the electron beam that is incident with the tilt angle being set to 0 degrees is the longest as illustrated in FIG. 4A. In other words, in a case where there is no bent in the hole pattern 44X, the response time of the electron beam that is incident in the center axis is the longest.

In a case where there is a bent in the hole pattern 44X, the response time of the electron beam with the tilt angle being set to a predetermined value (other than 0 degrees) is the longest as illustrated in FIG. 4B. In other words, in a case where there is a bent in the hole pattern 44X, the response time of the electron beam that is incident with an inclination of a predetermined angle with respect to the center axis is the longest. FIG. 4B illustrates a case where the longest response time Tₘₐₓ is attained when the tilt angle of the longest response time is θₘₐₓ.

The incidence path in the hole pattern 44X is determined in accordance with the cross sectional shape of the hole pattern 44X and the tilt angle when the electron beam is emitted. In other words, the incidence path changes in accordance with the cross sectional shape of the hole pattern 44X and the tilt angle. For example, the longest response time Tₘₐₓ is a response time in a case where the incidence path is the longest. The tilt angle of the longest response time θₘₐₓ corresponds to a tilt angle in a case where the incidence path is the longest. In the present embodiment, the amount of bent is calculated on the basis of a relationship of the condition for determining the incidence path (tilt angle and the like) and the response time. The conditions for determining the incidence path include not only the tilt angle but also the emission position of the electron beam explained later and the like.

FIGS. 5A and 5B are figures for explaining the amount of bent of the hole pattern. FIGS. 5A and 5B illustrate a position relationship of the bottom surface of the hole pattern 44X and the upper surface of the wire pattern 42X when seen from the upper surface side of the wafer WA. FIG. 5A illustrates a position relationship in a case where there is no bent in the hole pattern 44X. FIG. 5B illustrates a position relationship in a case where there is a bent in the hole pattern 44X.

In a case where the amount of bent of the hole pattern 44X is zero as illustrated in FIG. 5A, a position deviation amount between the bottom surface of the hole pattern 44X and the upper surface of the wire pattern 42X is zero. Therefore, a center C4 of the bottom surface of the hole pattern 44X (lowest bottom) and a center C2 of the upper surface of the wire pattern 42X are at the same position.

On the other hand, in a case where there is a bent in the hole pattern 44X as illustrated in FIG. 5B, a position deviation occurs between the bottom surface of the hole pattern 44X and the upper surface of the wire pattern 42X. Therefore, the center C4 of the bottom surface of the hole pattern 44X and the center C2 of the upper surface of the wire pattern 42X are different positions according to the position deviation amount.

In a case where there is a bent in the hole pattern 44X, the bottom surface of the hole pattern 44X deviates in terms of the position in the in-plane direction of the XY plane from the upper surface of the wire pattern 42X. The bottom surface of the hole pattern 44X deviates in terms of the position from the upper surface of the wire pattern 42X by, for example, a predetermined distance in the X direction and a predetermined distance in the Y direction.

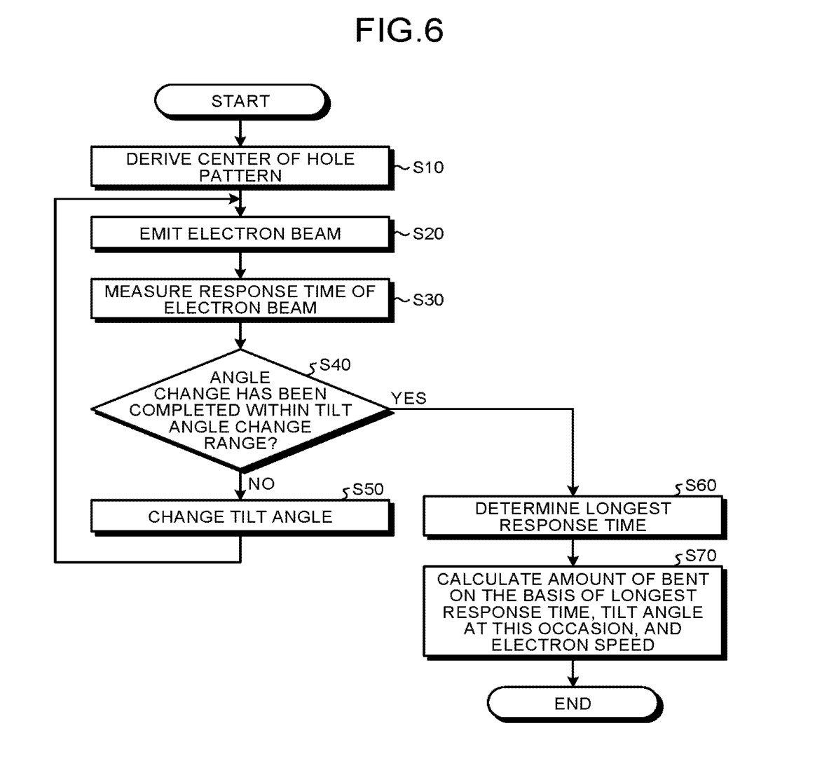

Subsequently, a measurement processing procedure of the amount of bent of the hole pattern 44X will be explained. FIG. 6 is a flowchart illustrating a bent amount measurement processing procedure according to the embodiment. When a semiconductor device is formed, a bent may occur in the hole pattern 44X after processing such as RIE (Reactive Ion Etching).

With regard to the hole pattern 44X which is the measurement target of the amount of bent, a plane electron image of the hole pattern 44X (an image of the upper surface portion) is obtained. This plane electron image may be captured by the measurement apparatus 100, or may be captured by other electron microscopes and the like.

The hole pattern 44X which is the measurement target is determined from the captured plane electron images. The measurement apparatus 100 selects the hole pattern 44X located at the measurement coordinate that is set in advance. For example, which of the amount of bent of the hole pattern 44X is adopted from among hole patterns 44X of plane electron images is adopted as the measurement target can be recorded in the measurement apparatus 100.

The measurement apparatus 100 derives the center coordinate of the upper surface portion of the hole pattern 44X (upper surface center coordinate) on the basis of the plane electron image of the selected hole pattern 44X (step S10). More specifically, the upper surface shape of the hole pattern 44X of the measurement target is fitted with a perfect circle or an ellipse, so that the upper surface center coordinate is determined.

The measurement apparatus 100 has the function of an electron microscope. The electron microscope emits an electron beam to a recessed shape pattern, detects a signal electron from the recessed shape pattern, and converts the signal quantity of the signal electron into brightness, thus obtaining a plane electron image in the emission area.

The upper surface center coordinate and the plane electron image are stored in the measurement apparatus 100. In the measurement apparatus 100, the electron gun 11 emits a single electron beam to the upper surface center coordinate (step S20). Then, the electron gun 11 sends first time information, which is a time when the electron beam was emitted, to the time measurement unit 22. It should be noted that the control unit 30 may send the first time information to the time measurement unit 22.

Each electron beam generated by the hole pattern 44X is delivered to the side of the filter 13. Among them, only the reflection electron of the electron beam passes through the filter 13 and is delivered to the reduction mechanism 14. Then, the reduction mechanism 14 reduces the speed of the reflection electron, and then the reflection electron is delivered to the detection device 21. Thus, the detection device 21 detects the reflection electron. The detection device 21 sends second time information, obtained when the reflection electron is detected, to the time measurement unit 22.

The time measurement unit 22 measures the response time from the emission of the electron beam to the detection thereof on the basis of the first time information sent from the electron gun 11 and the second time information sent from the detection device 21 (step S30).

At this occasion, the time interval of each of the electron beams emitted from the electron gun 11 is sufficiently long, and therefore, the time measurement unit 22 can easily associate the emitted electron beam and the detected reflection electron. Therefore, the time measurement unit 22 can easily measure the time-of-flight of the electron beam from the difference between the time when the electron beam was emitted and the time when the reflection electron was detected. It should be noted that the processing in step S20 and the processing in step S30 may be repeated multiple times in order to enhance the reliability of the measurement of the time-of-flight. The time measurement unit 22 sends the response time, which is the measurement result, to the bent amount calculation unit 23.

In the control unit 30, the range in which the tilt angle is changed (tilt angle change range) is set in advance. The control unit 30 determines whether all the angle change has been completed within the tilt angle change range or not (step S40).

In a case where the angle change has not been completed (step S40, No), the control unit 30 sends a change instruction of the tilt angle to the tilt mechanism 12. Accordingly, the tilt mechanism 12 changes the tilt angle of the electron beam (step 350). Therefore, the emitted electron beam is inclined with respect to the wafer WA. The tilt mechanism 12 sends the tilt angle to the bent amount calculation unit 23. It should be noted that the control unit 30 may send the tilt angle to the bent amount calculation unit 23.

Thereafter, the measurement apparatus 100 repeats the processing in steps S20 to S50. At this occasion, in the processing of steps S20 and S30, the track of the electron beam is adjusted so that the emitted electron beam passes through the upper surface center coordinate of the hole pattern 44X.

Then, when the control unit 30 determines that all the angle change has been completed within the tilt angle change range after the processing in step S30 (step S40, Yes), the bent amount calculation unit 23 determines the longest response time Tₘₐₓ from among the response times given by the time measurement unit 22 (step S60). Then, the bent amount calculation unit 23 calculates the amount of bent of the hole pattern 44X on the basis of the longest response time Tₘₐₓ, the tilt angle of the longest response time θₘₐₓ which is the tilt angle at this time, and the electron speed Ve of the electron beam (step S70). The bent amount calculation unit 23 uses, for example, the above expression (1) to calculate the amount of bent of the hole pattern 44X.

As described above, in the present embodiment, the electron beam is emitted while the tilt angle is changed. Then, the response time is measured for each tilt angle. Further, longest response time is determined. Then, the amount of bent is calculated on the basis of the longest response time, the tilt angle of the longest response time, and the electron speed.

Therefore, the direction and the amount of the bent can be derived without destroying the wafer WA as is done in a cross-section analysis observation. Since the measurement time of each hole pattern 44X is about several seconds to several dozen seconds per hole, the amount of bent can be measured with a much higher throughput than the section observation.

It should be noted that, since only the longest response time Tₘₐₓ is required to be known, it is not necessary to change the angle in all the tilt angle change range. As soon as the measurement apparatus 100 finds the longest response time Tₘₐₓ, the measurement apparatus 100 may omit emission of the electron beams using the other tilt angles.

In addition, in the present embodiment, a case where the incidence angle of the electron beam is changed by changing the tilt angle has been explained, but instead of changing the tilt angle, the incidence position of the electron beam may be changed.

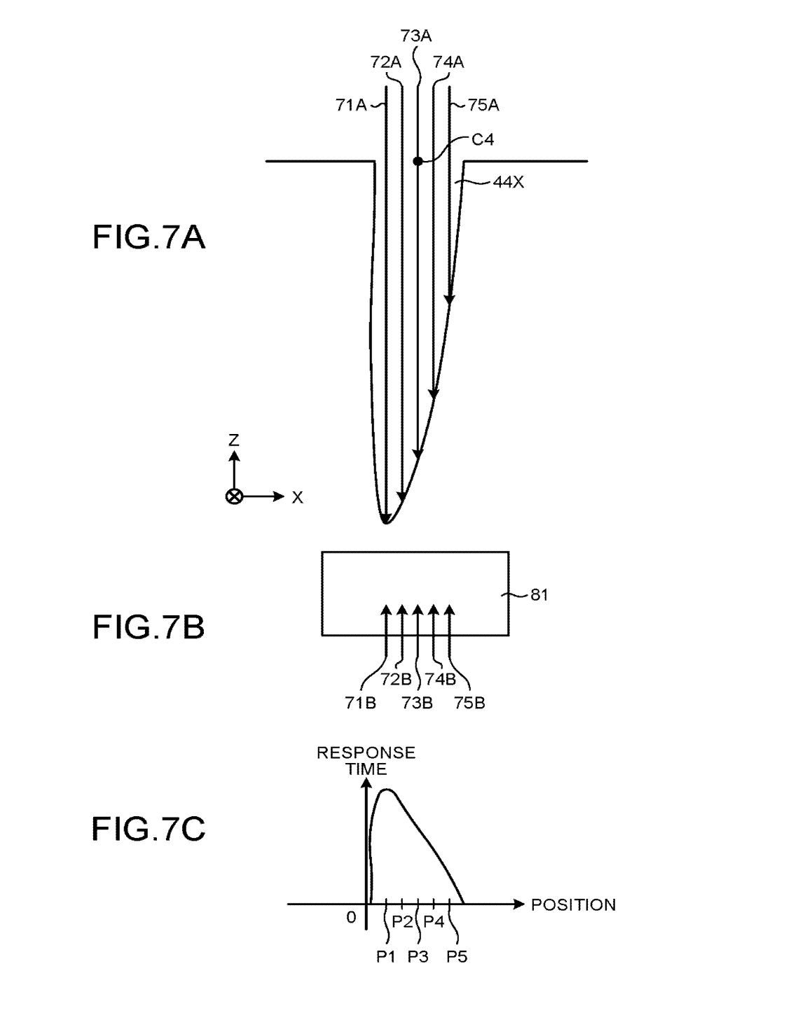

FIGS. 7A to 7C are figures for explaining a change of a response time in a case where the incidence position of the electron beam is changed. FIG. 7A illustrates an incidence path of an electron beam in a case where the incidence position is changed in the X direction. FIG. 7A illustrates the cross sectional shape of the hole pattern 44X and the incidence paths 71A to 75A of the electron beam. FIG. 7B illustrates a detection device 81 for detecting reflection electrons in a case where the incidence positions are changed. In FIG. 7B, the cross sectional shape of the detection device 81 and the paths 71B to 75B of the reflection electrons are illustrated. FIG. 7C illustrates response times corresponding to the positions in the hole pattern 44X. In the graph as illustrated in FIG. 7C, the horizontal axis is an electron beam emission position in the hole pattern 44X, and the vertical axis is a response time.

By moving the electron gun 11 or the wafer stage 31 in a direction in parallel with the XY plane, the electron beam having an incidence path in the vertical direction (Z direction) can be caused to be incident upon various positions in the hole pattern 44X. In this case, the electron beam can be caused to be incident upon various positions in the hole pattern 44X without changing the tilt angle.

The measurement apparatus 100 moves the electron gun 11 or the wafer stage 31, thereby changing a relative position of the electron gun 11 and the wafer WA in the XY plane. Therefore, as illustrated in FIG. 7A, the electron beam is incident upon within the hole pattern 44X in the incidence paths 71A to 75A in parallel with the Z direction.

The incidence path 73A is a path that passes through the center C4 of the hole pattern 44X and leads to the bottom side of the hole pattern 44X along the center axis. The incidence path 72A is a path in a case where the incidence position is changed by a first distance to the negative side in the X direction from the center C4. The incidence path 71A is a path in a case where the incidence position is changed by a second distance (second distance>first distance) to the negative side in the X direction from the center C4. The incidence path 74A is a path in a case where the incidence position is changed by the first distance to the positive side in the X direction from the center C4. The incidence path 75A is a path in a case where the incidence position is changed by the second distance to the positive side in the X direction from the center C4.

The detection device 81 as illustrated in FIG. 7B includes not only the function of the detection device 21 but also the function of detecting reflection electrons at various positions. The detection device 81 is, for example, a sensor having a CCD (Charge-Coupled Device). In a case where the incidence angle of the electron beam is changed, the measurement apparatus 100 is provided with the detection device 81 instead of the detection device 21.

The paths 71B to 75B of reflection electrons as illustrated in FIG. 7B correspond to incidence paths 71A to 75A, respectively. More specifically, those made when the electron beams of the incidence paths 71A to 75A are reflected in the hole pattern 44X are the paths 71B to 75B of the reflection electrons.

The detection device 81 is configured to detect the reflection electrons at various positions (pixels in a case of CCD). Then, the detection device 81 determines which of the incidence paths a reflection electron comes from on the basis of the detection position of the reflection electron. When the detection device 81 detects the reflection electron, the detection device 81 sends the time measurement unit 22 the incidence path corresponding to the detection position and the second time information when the reflection electron was detected.

When the incidence path of the electron beam is moved in the X direction, the response time according to the incidence position is measured as illustrated in FIG. 7C. The incidence positions P1 to P5 as illustrated in FIG. 7C correspond to the incidence paths 71A to 75A, respectively.

For example, the electron beam of the incidence path 75A passing through the incidence position P5 is reflected at a shallow position of the hole pattern 44X. Therefore, the response time of the electron beam emitted to the incidence position P5 becomes shorter.

The electron beam of the incidence path 74A passing through the incidence position P4 is reflected at a deeper position of the hole pattern 44X than the incidence path 75A. Therefore, the response time of the electron beam emitted to the incidence position P4 becomes longer than the incidence position P5.

The electron beam of the incidence path 73A passing through the incidence position P3 is reflected at a deeper position of the hole pattern 44X than the incidence path 74A. Therefore, the response time of the electron beam emitted to the incidence position P3 becomes longer than the incidence position P4.

The electron beam of the incidence path 72A passing through the incidence position P2 is reflected at a deeper position of the hole pattern 44X than the incidence path 73A. Therefore, the response time of the electron beam emitted to the incidence position P2 becomes longer than the incidence position P3.

The electron beam of the incidence path 71A passing through the incidence position P1 is reflected at the deepest position (the lowest bottom) of the hole pattern 44X. Therefore, the response time of the electron beam emitted to the incidence position P1 is the longest response time Tₘₐₓ.

The bent amount calculation unit 23 calculates, as the amount of bent of the hole pattern 44X, a distance between the incidence position P1, at which the longest response time Tₘₐₓ is attained, and the incidence position P3 of the electron beam passing through the center C4 of the hole pattern 44X.

In FIG. 7, the incidence paths 71A to 75A are changed in the X direction, but the incidence paths 71A to 75A may be changed in the Y direction. Alternatively, the incidence paths 71A to 75A may be changed in the X direction and the Y direction.

When a semiconductor device is manufactured, a circuit pattern and the like is formed on the wafer WA. In a manufacturing step of a semiconductor device, multiple layers constituted by different materials and layouts are stacked in a three dimensional manner, and complicated circuits are formed. Among them, several layers play the role of forming contacts (connection units) for connecting circuit layers of a lower layer and an upper layer. Such contacts are formed in a hole shape such as the hole pattern 44X that can be arranged with a high degree of density.

When the circuit pattern is formed, a pattern engraved in a mask which is an original version is transferred to a resist applied to the wafer WA by using a photolithography technique, an imprint lithography technique, and the like. Thereafter, the resist pattern is transferred to the wafer WA by using processing means such as dry etching technique.

In a case where the interval (pitch) of the pattern to be processed is narrow, and it is necessary to perform processing to a deep portion, and more specifically, it is necessary to form a pattern with a high aspect ratio, the level of difficulty in the processing becomes higher. In particular, when a semiconductor device recently attains a higher level of density, it becomes difficult to uniformly process the entire surface of the substrate such as the wafer WA. When a pattern of a high aspect ratio is formed, an inspection is performed to determine whether the pattern of the high aspect ratio is formed appropriately.

In the present embodiment, the measurement apparatus 100 emits an electron beam to the hole pattern 44X by changing the tilt angle to various angles. Then, the measurement apparatus 100 calculates the amount of bent of the hole pattern on the basis of the tilt angle of the longest response time θₘₐₓ, the longest response time Tₘₐₓ, and the electron speed Ve. Therefore, the amount of bent of the hole pattern 44X can be easily measured.

In a case of a section observation using SEM, it takes a measurement time of two to three days to inspect the amount of bent, and the number of measurement points is limited to several to several dozen points. In a measurement of bent according to the present embodiment, it takes about several seconds to several dozen seconds per hole, and therefore, several dozen to several thousand points can be measured. Therefore, the quality management significantly improves in manufacturing process of a semiconductor device.

For example, the measurement of the amount of bent using the measurement apparatus 100 is performed for each contact formation step in the wafer process. When a semiconductor device is manufactured, deposition processing to the wafer WA, application processing to a resist, exposure processing using a mask, development processing, etching processing, measurement processing according to the present embodiment, and the like are repeated.

When a semiconductor device is manufactured, a measurement result (the amount of bent) obtained by measurement processing according to the present embodiment is given as a feedback. In this case, during exposure processing using a mask, exposure processing is performed to solve the amount of bent. In a case where, for example, the amount of bent is large in a peripheral portion of the wafer WA, a parameter for position deviation during exposure is set for another wafer (a subsequent wafer) so as to eliminate the amount of bent at the peripheral portion of the wafer. Therefore, in a subsequent wafer, the amount of bent can be suppressed. In a case where the position of the center of the hole pattern 44X is deviated, this position deviation is also corrected during the exposure processing.

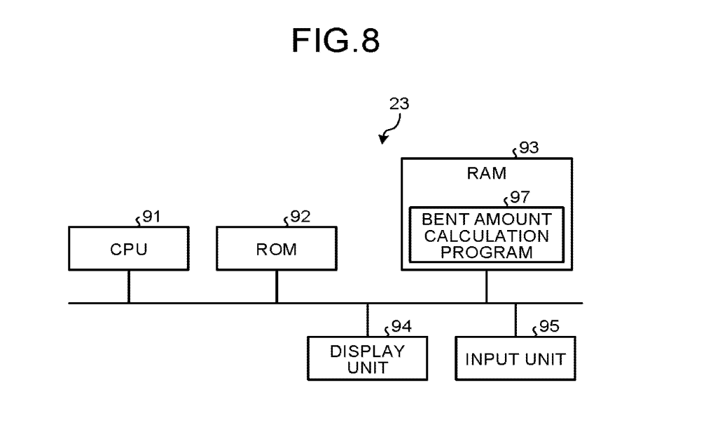

Subsequently, a hardware configuration of the bent amount calculation unit 23 will be explained. FIG. 8 is a figure for illustrating a hardware configuration of the bent amount calculation unit. The bent amount calculation unit 23 includes a CPU (Central Processing Unit) 91, ROM (Read Only Memory) 92, RAM (Random Access Memory) 93, a display unit 94, and an input unit 95. The bent amount calculation unit 23 is configured such that the CPU 91, the ROM 92, the RAM 93, the display unit 94, and the input unit 95 are connected via a bus line.

The CPU 91 determines a pattern by using a bent amount calculation program 97 which is a computer program. The bent amount calculation program 97 is a computer program product including a nontransitory computer readable recording medium including multiple commands for calculating the amount of bent of the hole pattern 44X and the like that can be executed by a computer. The bent amount calculation program 97 causes a computer to calculate the amount of bent with the multiple commands.

The display unit 94 is a display apparatus such as a liquid crystal monitor, and the display unit 94 displays the response time of the electron beam, the tilt angle, the relationship between the tilt angle and the response time (measurement result), the tilt angle of the longest response time θₘₐₓ the longest response time Tₘₐₓ, the amount of bent of the hole pattern 44X, and the like, on the basis of an instruction given by the CPU 91. The input unit 95 is constituted by including a mouse and a keyboard, and inputs instruction information externally input from a user (parameters and the like required to calculate the amount of bent). The instruction information that is input with the input unit 95 is sent to the CPU 91.

The bent amount calculation program 97 is stored in the ROM 92, and is loaded via a bus line to the RAM 93. FIG. 8 illustrates a state where the bent amount calculation program 97 is loaded to the RAM 93.

The CPU 91 executes the bent amount calculation program 97 loaded to the RAM 93. More specifically, the bent amount calculation unit 23 executes various kinds of processing when CPU 91 reads the bent amount calculation program 97 from the ROM 92 and extracts the bent amount calculation program 97 to a program storage area in the RAM 93 in accordance with an instruction input with the input unit 95 by the user. The CPU 91 temporarily stores various kinds of data generated in various kinds of processing to the data storage area formed in the RAM 93.

It should be noted that the measurement apparatus 100 may not have the reduction mechanism 14. In this case, the reflection electron having passed the filter 13 is delivered to the detection device 21. It should be noted that the measurement apparatus 100 may not have the filter 13. In this case, after the electron beam is emitted to the wafer WA, the detection device 21 first detects, as reflection electrons, electrons reflected by the wafer WA, and does not detect other secondary electrons and the like.

The bent amount calculation unit 23 may predict the shape of the hole pattern 44X on the basis of the relationship (profile shape) of the tilt angle and the response time as illustrated in FIG. 4. The profile shape corresponds to the shape of the hole pattern 44X. For example, in a case where the profile shape has a large top portion, the portion of the bottom surface of the hole pattern 44X is large. In a case where the top portion of the profile shape is small, the portion of the bottom surface of the hole pattern 44X is small.

As described above, according to the embodiment, the amount of bent of the hole pattern 44X is calculated on the basis of the response time of the electron beam emitted to the hole pattern 44X and the tilt angle of the electron beam emitted to the hole pattern 44X. Therefore, the amount of bent of the hole pattern 44X can be measured in a short time without destroying the wafer WA.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A measurement apparatus comprising:
an electron emission unit that emits an electron beam;
a detection unit that detects a reflection electron reflected by a recessed shape pattern which is a measurement target pattern;
a time measurement unit that measures a response time which is a time from when the electron beam is emitted to when the reflection electron is detected; and
a bent amount calculation unit that calculates, as an amount of bent of the recessed shape pattern, a position deviation amount between an upper surface portion and a bottom surface portion of the recessed shape pattern, on the basis of a condition for determining the incidence path of the electron beam to the recessed shape pattern, and the response time.

2. The measurement apparatus according to claim 1, further comprising a tilt mechanism that changes the tilt angle of the electron beam with which the electron beam is emitted to the recessed shape pattern,
wherein the bent amount calculation unit calculates the amount of bent by using the tilt angle as the condition.

3. The measurement apparatus according to claim 2, wherein the bent amount calculation unit calculates the amount of bent on the basis of a longest response time chosen from among the response times in a case where the electron beam is emitted with a plurality of tilt angles, a tilt angle in a case of the longest response time that is chosen from among the plurality of tilt angles, and a speed of the electron beam.

4. The measurement apparatus according to claim 2, wherein the tilt mechanism inclines the electron beam in first and second directions.

5. The measurement apparatus according to claim 2, wherein the electron emission unit and the tilt mechanism emit the electron beam so that the electron beam passes through a center of the upper surface portion of the recessed shape pattern.

6. The measurement apparatus according to claim 5, wherein the bent amount calculation unit calculates, as the amount of bent, a distance from the center.

7. The measurement apparatus according to claim 1, further comprising a reduction mechanism that reduces the speed of the reflection electron and delivers the reflection electron to the detection unit.

8. The measurement apparatus according to claim 1, further comprising a filter that allows a reflection electron of a primary electron, from among electrons generated when the electron beam is emitted to the recessed shape pattern, to be passed to a side of the detection unit, and cuts off other electrons.

9. The measurement apparatus according to claim 1, wherein the electron emission unit is configured to be able to change an emission position of the electron beam,
wherein the detection unit detects a reflection electron at a position according to the incidence position of the electron beam to the recessed shape pattern, and
the bent amount calculation unit calculates the amount of bent by using the emission position as the condition.

10. A measurement method comprising:
emitting an electron beam;
detecting a reflection electron reflected by a recessed shape pattern which is a measurement target pattern;
measuring a response time which is a time from when the electron beam is emitted to when the reflection electron is detected; and
calculating, as an amount of bent of the recessed shape pattern, a position deviation amount between an upper surface portion and a bottom surface portion of the recessed shape pattern, on the basis of a condition for determining the incidence path of the electron beam to the recessed shape pattern, and the response time.

11. The measurement method according to claim 10, comprising:
changing the tilt angle of the electron beam with which the electron beam is emitted to the recessed shape pattern; and
calculating the amount of bent by using the tilt angle as the condition.

12. The measurement method according to claim 11, wherein the amount of bent is calculated on the basis of a longest response time chosen from among the response times in a case where the electron beam is emitted with a plurality of tilt angles, a tilt angle in a case of the longest response time that is chosen from among the plurality of tilt angles, and a speed of the electron beam.

13. The measurement method according to claim 11, wherein the electron beam is inclined in first and second directions.

14. The measurement method according to claim 11, wherein the electron beam is emitted so that the electron beam passes through a center of the upper surface portion of the recessed shape pattern.

15. The measurement method according to claim 14, wherein a distance from the center is calculated as the amount of bent.

16. The measurement method according to claim 10, wherein the speed of the reflection electron is reduced and thereafter the reflection electron is detected.

17. The measurement method according to claim 10, wherein a reflection electron of a primary electron, from among electrons generated when the electron beam is emitted to the recessed shape pattern, is allowed to be passed, and other electrons are cut off, and the passed reflection electron is detected.

18. The measurement method according to claim 10, wherein an emission position of the electron beam is changed;
a reflection electron is detected at a position according to the incidence position of the electron beam to the recessed shape pattern, and
the amount of bent is calculated by using the emission position as the condition.

19. A manufacturing method of a semiconductor device, the method comprising:
emitting an electron beam;
detecting a reflection electron reflected by a first recessed shape pattern which is a measurement target pattern;
measuring a response time which is a time from when the electron beam is emitted to when the reflection electron is detected;
calculating, as an amount of bent of the recessed shape pattern, a position deviation amount between an upper surface portion and a bottom surface portion of the recessed shape pattern, on the basis of a condition for determining the incidence path of the electron beam to the recessed shape pattern, and the response time; and
correcting position deviation when a second recessed shape pattern is formed on a substrate, on the basis of the amount of bent.

20. The manufacturing method of the semiconductor device according to claim 19, wherein the first recessed shape pattern is a processed pattern after a resist pattern is processed as a mask,
the second recessed shape pattern is a resist pattern.
